(19) United States
(12) Patent Application Publication
(10) Pub. No.: US 2011/0174357 A1
(43) Pub. Date: Jul. 21, 2011

(54) Temperature Control Device for Thin-Type Photovoltaic Thermal Module

(76) Inventor: Yaue-Sheng Chang, Longtan (TW)

(21) Appl. No.: 12/688,876

(22) Filed: Jan. 16, 2010

(51) Int. Cl. H01L 31/052

(52) U.S. Cl. 136/246

(57) ABSTRACT

Provided is a temperature control device for a thin-type photovoltaic thermal module, including a conductive layer and a conductor having a top surface coupled to a bottom surface of the photovoltaic thermal module via the conductive layer therebetween. The conductor is internally provided with a plurality of channels arranged in parallel. A liquid is configured to flow from an end of the conductor to another end of the conductor so as to allow heat to enter or exit the conductor for enabling the photovoltaic thermal module to generate power at a steady power level.

### BACKGROUND OF THE INVENTION

1. Technical Field

The present invention relates to temperature control devices for photovoltaic thermal modules, and more particularly, to a structure for removing heat from or heating up a thin-type photovoltaic thermal module.

2. Description of Related Art

Taiwanese Utility Model Application No. TWP96201310 suggests a heat dissipation module for use with a focused solar panel so as for the heat dissipation module to be provided on the bottom surface of a solar chip, primarily because the focused solar panel receives so much thermal energy that the solar chip is overheated, and thus heat has to be removed from the focused solar panel. The aforesaid structure comes in two types, namely the water-cooled type and the air-cooled type. Taiwan Utility Model Application No. TWP96201310 puts forth a good notion and yet, as disclosed therein, its application is limited to said focused solar panels and is not applicable to other types of solar panels, thus being restricted against all-inclusive application. In view of the aforesaid drawback of the prior art, the inventor of the present invention considers it imperative to overcome the aforesaid drawback of the prior art so as to meet user needs better.

### BRIEF SUMMARY OF THE INVENTION

It is a primary objective of the present invention to provide a temperature control device for a thin-type photovoltaic thermal module. A solar chip is always thin, regardless of whether the solar chip is of the polysilicon type or the film type. A thin-type photovoltaic thermal module comprises an upper thin plate-shaped layer of solar chips put together in arrays and a lower thin plate-shaped layer of solar chips put together in arrays. The tipper and lower thin plate-shaped layers of solar chips are packaged together by a package membrane coated with an abrasion-resistant layer. However, the efficiency of operation of the thin-type photovoltaic thermal module deteriorates at extremely high or low temperature and thus results in a waste of energy to the disappointment of investors. The present invention provides a liquid-cooled or liquid-heated circulatory supply structure that comprises a conductive layer in full contact with a photovoltaic thermal module to thereby exchange heat therewith by supplying heat to or removing heat from the photovoltaic thermal module in a bi-directional manner, and the heat thus removed from the photovoltaic thermal module is transferred via a pipeline to a remote end for storage or disposed of by heat exchange. The aforesaid structure of the present invention enables the photovoltaic thermal module to absorb energy and convert the absorbed energy into electric power most efficiently.

To achieve the above and other objectives, the present invention provides a structure comprising a conductive layer and a conductor having a top surface coupled to a bottom surface of a photovoltaic, thermal module via the conductive layer therebetween, wherein the conductor is internally provided with a plurality of channels arranged in parallel so as for a liquid to flow from an end of the conductor to another end or the conductor.

### BRIEF DESCRIPTION OF THE SEVERAL VIEWS OF THE DRAWINGS

To enable persons skilled in the art to gain insight into technical solutions, means, and effects of the present invention with a view to achieving the predetermined objectives of the present invention and have a good understanding of the objectives, technical features, and advantages of the present invention, reference is now made to a feasible preferred embodiment illustrated hereunder in conjunction with the accompanying drawing, in which:

FIG. 1 is an exploded view of the present invention;

FIG. 2 is a perspective view of the present invention; and

FIG. 3 is a schematic side view of storage tanks connected together according to the present invention.

### DETAILED DESCRIPTION OF THE INVENTION

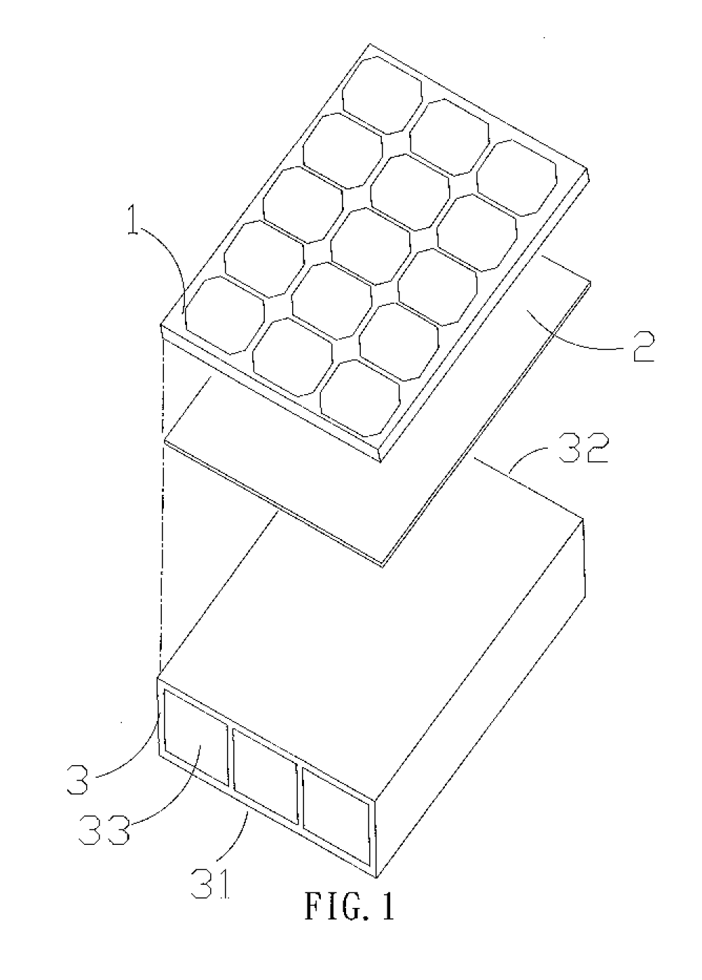

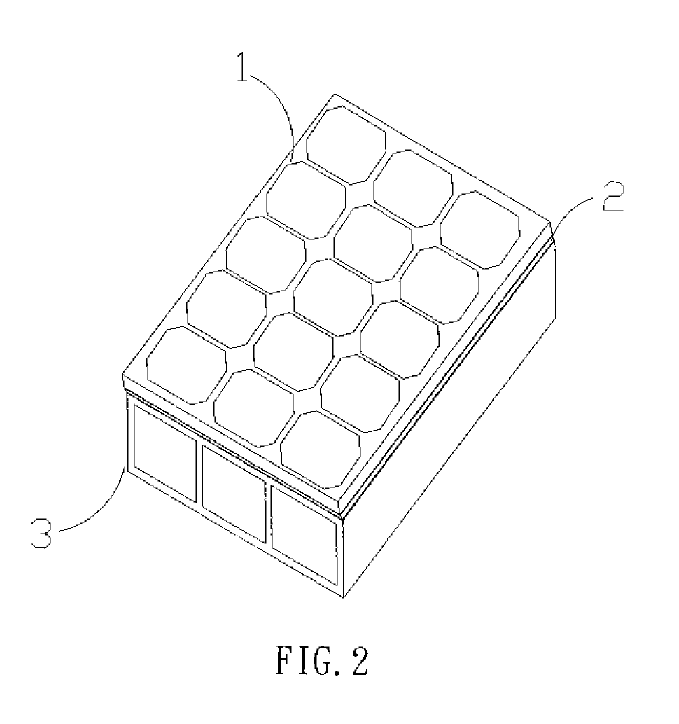

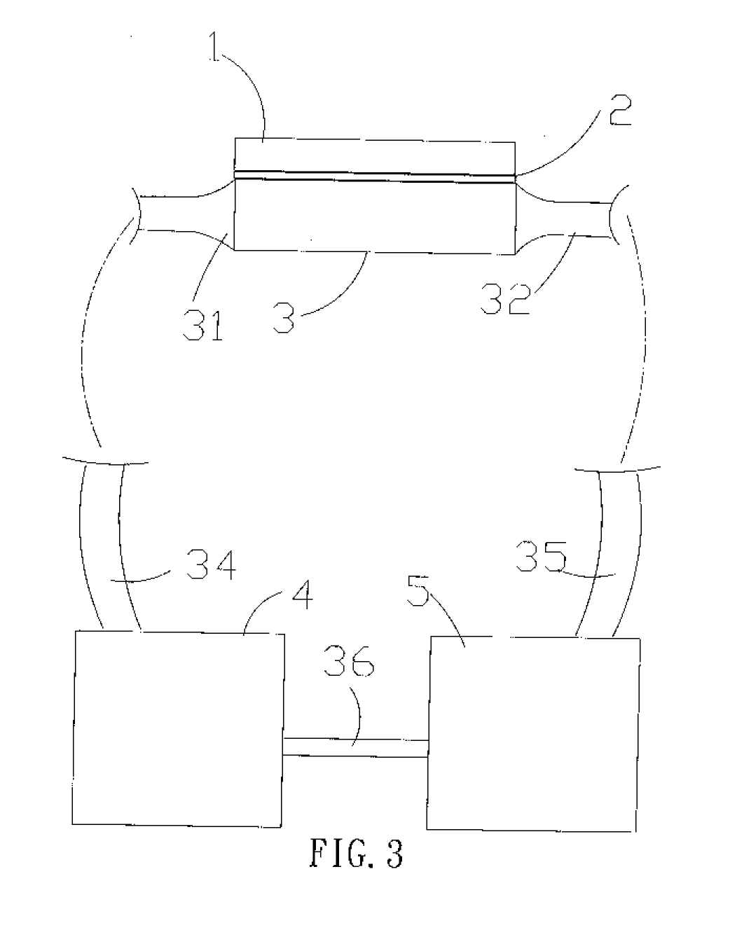

A temperature control device for a thin-type photovoltaic thermal module is provided by the present invention and illustrated with FIG. 1 to FIG. 3. The temperature control device comprises a conductive layer 2 and a conductor 3 having a top surface coupled to a bottom surface of a thin-type photovoltaic thermal module 1 via the conductive layer 2 therebetween. The conductor 3 is internally provided with a plurality of channels 33 arranged in parallel. A liquid is configured to flow from an end 31 of the conductor 3 to another end 32 of the conductor 3: The liquid flowing in the aforesaid manner allows heat to enter or exit the conductor 3 so as for the photovoltaic thermal module 1 to generate power at a steady power level. Refer to FIG. 1 and FIG. 2 for the framework of the present invention. The conductor 3 is made of a metal of high thermal conductivity, such as aluminum, copper, or gold. The conductive layer 2 is a layer of thermal grease. Referring to FIG. 3, two ends of the conductor 3 are connected to at least a hot storage tank 4 and at least a cold storage tank 5 via multiple abreast pipelines 34, 35 (though single pipelines are shown in FIG. 3), respectively. The hot storage tank 4 and the cold storage tank 5 are in fluid communication by means of a pipeline 36 therebetween. The aforesaid arrangement is required for circulation of the liquid. However, in case of a great difference in temperature between two said ends 31, 32 of the conductor 3, circulation of the liquid will be eliminated; instead, supply of cold liquid and collection of hot liquid take place, or vice versa. The hot storage tank 4 may he provided with a heat dissipating apparatus (not shown, for example, cooling fins). Alternatively, the hot liquid is removed from the hot storage tank 4 for direct usage. In such case, the photovoltaic thermal module acts as a heater itself. To prevent undesirably low temperature or the liquid in the hot storage tank 4, as in the case of winter in boreal regions, the hot storage tank 4 may be equipped with a heating apparatus (not shown, for example, a heating pipe), and the pipeline 34 is configured to convey hot liquid reversely, that is, feeding the hot liquid to the conductor 3. The liquid, which is water or oil, is conveyed by a pump. A thermally insulating layer (not shown) is provided on a bottom surface of the conductor 3 for maintaining the temperature of the liquid in the conductor.

In conclusion, the present invention provides a temperature control device for a thin-type photovoltaic thermal module, to apply the principle of heat transfer and heat exchange between cold liquid and hot liquid to a photovoltaic thermal module comprising solar chips arranged in arrays such that the temperature of the photovoltaic thermal module stays within a particular temperature range (set by a thermostat). Hence, the present invention enhances the efficiency of photoelectric conversion of the solar chips, enables hot water to be withdrawn for immediate use or stored for later use in the form of thermal energy, and provides indoor heating or indoor air conditioning. Accordingly, the present invention is conducive to efficient energy use, has high industrial applicability, and has novelty over the prior art.

The above-described descriptions of the detailed embodiment and the accompanying drawings are intended to illustrate the preferred implementation according to the present invention, and are not intended to limit the scope of the present invention. Accordingly, various modifications and variations made to the preferred embodiment of the present invention and structures analogous thereto and put forth in accordance with the spirit embodied in the appended claims should fall within the scope of the present invention as defined by the appended claims.

What is claimed is:

1. A temperature control device for a thin-type photovoltaic thermal module, the temperature control device comprising:
a conductive layer; and
a conductor having a top surface coupled to a bottom surface of the photovoltaic thermal module via the conductive layer therebetween, the conductor being internally provided with a plurality of channels arranged in parallel, wherein a liquid flows from an end of the conductor to another end of the conductor to thereby allow heat to enter or exit the conductor so as for the photovoltaic thermal module to generate power at a steady power level.

2. The temperature control device of claim 1, wherein the conductor is made of a metal of high thermal conductivity and the metal is aluminum, copper, or gold.

3. The temperature control device of claim 1, wherein two ends of the conductor arc connected to at least a hot storage tank and at least a cold storage tank via multiple abreast pipelines, respectively.

4. The temperature control device of claim 3, wherein the hot storage tank and the cold storage tank are in fluid communication.

5. The temperature control device of claim 3, wherein the hot storage tank is provided with a heat dissipating apparatus.

6. The temperature control device of claim 3, wherein the hot storage tank is provided with a heating apparatus.

7. The temperature control device of claim 1, wherein a thermally insulating layer is provided on a bottom surface of the conductor.

8. The temperature control device of claim 1, wherein the liquid is water or oil.
